(19) United States
(12) Patent Application Publication
(10) Pub. No.: US 2026/0234798 A1
(43) Pub. Date: Aug. 13, 2026

(54) FLOW-OVER-VAPOR PRECURSOR DELIVERY

(71) Applicant: Lam Research Corporation, Fremont, CA (US)

(72) Inventors: Sivananda Krishnan Kanakasabapathy, Pleasanton, CA (US); Michel Garcia, Tigard, OR (US); David Joseph Mandia, Lake Oswego, OR (US); Panya Wongsenakhum, Fremont, CA (US)

(21) Appl. No.: 19/158,319

(22) PCT Filed: Feb. 26, 2024
(86) PCT No.: PCT/US2024/017348

§ 371 Date: Aug. 20, 2025

Related U.S. Application Data
(60) Provisional application No. 63/488,084, filed on Mar. 2, 2023.

(51) Int. Cl. C23C 16/455; C23C 16/448; C23C 16/52

(52) U.S. Cl. CPC C23C 16/45561; C23C 16/4481; C23C 16/52

(57) ABSTRACT

Various examples relate to systems and methods for determining a dose of a precursor. The system may include a flow splitter configured to split a flow of carrier gas into a first pathway and a second pathway; a first charge volume positioned in the first pathway and a second charge volume positioned in the second pathway; an ampoule comprising the precursor positioned within the second pathway; and a pressure gauge configured to measure a differential pressure between (i) a first location in the first pathway, and (ii) a second location in the second pathway.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

Various semiconductor processing methods involve delivery of one or more precursor to a processing chamber. In some cases, a flow-over-vapor technique is used. Such techniques are particularly valuable for delivering corrosive low vapor pressure precursors, which may otherwise decompose or corrode when heated.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various examples herein relate to systems and methods for determining and/or providing a dose of a precursor to a processing chamber. Such systems and methods are particularly useful in the context of flow-over-vapor precursors. In one aspect of the disclosed examples, a system for providing a dose of a precursor a processing chamber is provided, the system including: an inlet configured to allow a flow of a carrier gas into the system; a flow splitter in fluid communication with the inlet and configured to split the flow of the carrier gas into a first stream and a second stream, where the first stream is delivered to a first pathway and the second stream is delivered to a second pathway; a first charge volume positioned in the first pathway, wherein the first stream passes through the first charge volume, and a second charge volume positioned in the second pathway, wherein the second stream passes through the second charge volume; an ampoule including the precursor, the ampoule positioned within the second pathway, where when the second stream passes the ampoule at a sufficiently high temperature, the precursor is entrained within the second stream; and a pressure gauge configured to measure a differential pressure between (i) a first location positioned in the first pathway, and (ii) a second location positioned in the second pathway.

In some examples, the system includes the first charge volume and the second charge volume. In many such examples, the first location is in the first charge volume and the second location is the second charge volume. In these or other examples, the first charge volume and the second charge volume may be precision matched to one another. In these or other examples, the system may further include a fourth flow control device positioned in the first pathway and a fifth flow control device positioned in the second pathway, where the fourth and fifth flow control devices are precision matched to one another. In some such examples, the fifth flow control device may be upstream of the ampoule within the second pathway.

In various examples, the second pathway may include a first leg and a second leg, the ampoule may be positioned within the second leg, and a plurality of valves may be provided in the second pathway to alternatively (a) allow for the ampoule to be in fluidic communication with the inlet and with the second charge volume such that the second stream passing through the second charge volume includes both the carrier gas and the precursor, and (b) to prevent fluidic communication between the ampoule and either the inlet or the second charge volume such that the second stream passing through the second charge volume includes the carrier gas and is absent the precursor.

In some examples, the system may further include a controller configured to cause measuring the differential pressure between the first location and the second location. In some such examples, the controller may be further configured to cause determining the dose of precursor provided to the processing chamber based on the measured differential pressure between the first location and the second location. In these or other examples, the controller may be configured to cause determining a dose of precursor provided to the processing chamber based on the measured differential pressure between the first location and the second location, as modified by a zero error that accounts for differences between the first pathway and the second pathway. In some such examples, the zero error may correspond to a differential pressure between the first charge volume and the second charge volume after the first charge volume and the second charge volume have been evacuated to their base pressure and while the ampoule is not in fluidic communication with the second charge volume. In these or other examples, first pathway may be maintained at a first temperature and the second pathway may be maintained at a second temperature, the first and second temperatures being within about 1° C. of one another. In these or other examples, the controller may be configured to cause delivering a target dose of precursor to the processing chamber upon reaching a target differential pressure between the first location and the second location.

In another aspect of the disclosed examples, a system for providing a dose of a precursor a processing chamber is provided, the system including: an inlet configured to allow a flow of a carrier gas into the system; a flow splitter in fluid communication with the inlet and configured to split the flow of the carrier gas into a first stream and a second stream, where the first stream is delivered to a first pathway and the second stream is delivered to a second pathway; a first flow control device, a second flow control device, and a third flow control device, wherein the first flow control device and the second flow control device are each positioned in the first pathway and the third flow control device is positioned in the second pathway, wherein the first stream passes through the first flow control device and through the second flow control device, wherein the second stream passes through the third flow control device, and wherein at least one of the first flow control device, the second flow control device, and/or the third flow control device is a variable flow control device configured to provide a variable flow resistance; an ampoule including the precursor, the ampoule positioned within the second pathway, where when the second stream passes the ampoule at a sufficiently high temperature, the precursor is entrained within the second stream; and a pressure gauge configured to measure a differential pressure between (i) a first location positioned in the first pathway, and (ii) a second location positioned in the second pathway.

In some examples, the system includes a controller that is configured to cause measuring the differential pressure between the first location and the second location while the flow of the carrier gas is at a first temperature, the first temperature being sufficiently low that substantially no precursor is entrained in the second stream, adjusting the variable flow resistance of the variable flow control device such that the differential pressure between the first location and the second location reads zero, raising the temperature of the carrier gas from the first temperature to a second temperature, the second temperature being sufficiently high that the precursor becomes entrained in the second stream, and measuring the differential pressure between the first location and the second location while the flow of the carrier gas is at the second temperature.

In another aspect of the disclosed examples, a method for determining a dose of precursor to be provided to a processing chamber is provided, the method including: splitting a flow of a carrier gas into a first stream delivered to a first pathway and a second stream delivered to a second pathway; passing the second stream over an ampoule positioned in the second pathway, the ampoule comprising the precursor, wherein when the second stream passes the ampoule at a sufficiently high temperature, the precursor is entrained within the second stream; passing the first stream into a first charge volume positioned in the first pathway and passing the second stream into a second charge volume positioned in the second pathway; measuring a differential pressure between the first charge volume and the second charge volume; and determining the dose of precursor to be provided to the processing chamber based on the measured differential pressure between the first charge volume and the second charge volume.

In some examples, determining the dose of precursor to be provided to the processing chamber may include determining a corrected differential pressure between the first charge volume and the second charge volume, the corrected differential pressure corresponding to the measured differential pressure modified by a zero error that accounts for differences between the first pathway and the second pathway.

In some examples, the method may further include determining a zero error by measuring the differential pressure between the first charge volume and the second charge volume while the first charge volume and the second charge volume are evacuated to their base pressure and while the ampoule is not in fluidic communication with the second charge volume. In some such examples, the method may further include determining a corrected differential pressure between the first charge volume and the second charge volume by subtracting the zero error from the measured differential pressure between the first charge volume and the second charge volume, where the dose of precursor is determined based on the corrected differential pressure between the first charge volume and the second charge volume.

In these or other examples, the method may further include providing an alert and/or ceasing operation of the processing chamber upon detecting that the zero error is greater than a threshold zero error.

In various examples, the method may further include delivering a target dose of precursor to the processing chamber upon reaching a target differential pressure between the first charge volume and the second charge volume.

In these or other examples, the first stream and the second stream may be provided to a third charge volume, an additional gas may be provided to the third charge volume to further dilute the precursor, and the third charge volume may be discharged to the processing chamber upon reaching a target pressure within the third charge volume.

In another aspect of the disclosed examples, a method of determining a dose of precursor to be provided to a processing chamber is provided, the method including: splitting a flow of a carrier gas into a first stream delivered to a first pathway and a second stream delivered to a second pathway; passing the first stream through a first flow control device and through a second flow control device, where the first flow control device and the second flow control device are each positioned in the first pathway; passing the second stream through a third flow control device positioned in the second pathway, and passing the second stream through or over an ampoule positioned in the second pathway, where the ampoule includes the precursor, and where at least one of the first flow control device, the second flow control device, and/or the third flow control device is a variable flow control device configured to provide a variable flow resistance; measuring a differential pressure between a first location positioned in the first stream and a second location positioned in the second stream while the carrier gas is at a first temperature; adjusting the variable flow resistance of the variable flow control device such that the differential pressure between the first location and the second location is zero; raising a temperature of the carrier gas to a second temperature, where the second temperature is sufficiently high to entrain some of the precursor in the second stream; measuring the differential pressure between the first location and the second location while the carrier gas is at the second temperature; and determining the dose of precursor based at least in part on the differential pressure measurements at the first temperature and at the second temperature.

These and other aspects are described further below with reference to the drawings.

### BRIEF DESCRIPTION OF THE DRAWINGS

FIG. 1 illustrates a system for providing dose control, which may be used in examples where flow-over-vapor is used for precursor delivery.

FIG. 2 presents a flowchart for a method of providing dose control in examples where flow-over vapor is used for precursor delivery.

FIG. 3 presents a flowchart for a method of calculating a zero error correction that may be used in some examples.

FIGS. 4 and 5 present charts showing pressure vs. time, which may be used to calculate a dose of precursor according to various examples herein.

FIG. 6 illustrates a system for providing dose control, which may be used in various implementations.

FIG. 7 presents a flowchart for a method of providing dose control where flow-over-vapor is used for precursor delivery.

FIG. 8 depicts an example deposition apparatus that may include the dose control system shown in FIG. 1 according to various examples.

### DETAILED DESCRIPTION

In the following description, numerous specific details are set forth to provide a thorough understanding of the presented examples. The disclosed examples may be practiced without some or all of these specific details. In other instances, well-known process operations have not been described in detail to not unnecessarily obscure the disclosed examples. While the disclosed examples will be described in conjunction with the specific examples, it will be understood that it is not intended to limit the disclosed examples.

Many semiconductor processing methods involve delivery of one or more precursor to a processing chamber. Such processing methods include, but are not limited to, deposition methods, etching methods, substrate treatment and conditioning methods, etc. Particular examples of methods that may benefit from the techniques disclosed herein include, but are not limited to, atomic layer deposition, chemical vapor deposition, atomic layer etching, epitaxy, etc.

While some precursors are relatively easy to deliver, others present greater challenges. For instance, liquid and solid precursors must often be vaporized before delivery to a vapor-based processing chamber. Direct vaporization and vapor delivery through appropriate plumbing (a technique often referred to as direct vapor draw) is used in some instances. In other instances, such direct vaporization is avoided due to challenges associated with heating certain precursors. For example, there are several low vapor pressure precursors that can decompose and/or corrode downstream processing equipment when the precursors are heated. In such cases, it is often preferable to use a flow-over-vapor precursor delivery system. Examples of such precursors include, but are not limited to, MoO₂Cl₂, MoCl₅, WCl₅, HFCl₄, etc.

In a flow-over-vapor system, an inert carrier gas (e.g., often one or more of Ar, He, N₂, etc.) at a sufficiently low temperature is flowed over an ampoule containing a relevant precursor to be delivered to a processing chamber. The physical flow of the inert gas entrains vaporizing molecules of the precursor and increases the rate of vaporization by constantly evacuating the headspace above the ampoule and preventing re-condensation.

In such flow-over-vapor systems, there is no direct measure of the rate of vaporization of the precursor. While the combined flow rate of precursor and inert gas can be measured, it has been difficult or impossible to accurately determine the flow of precursor, as opposed to inert gas, since the precursor and inert gas are indistinguishable within the combined flow.

Various techniques have been used to estimate the flow of precursor within a flow-over-vapor delivery system. Each of these techniques presents certain drawbacks. For instance, one technique involves bypass-enabled differential metrology. In this technique, the pressure within a charge volume in the precursor delivery plumbing system is compared (1) while the charge volume is not in fluidic communication with the ampoule (e.g., while the ampoule is effectively being bypassed such that there is no precursor in the charge volume), and (2) while the charge volume is in fluidic communication with the ampoule containing the precursor (which has been opened and allowed to come to equilibrium with the charge volume). The incremental increase in pressure during (2) compared to (1) is attributed to the precursor, and the dose of precursor is estimated based on this increase. This technique is relatively simple, and it works in cases where the precursor has a vapor pressure that is substantially greater (e.g., greater than 10×) than the gauge error on the pressure sensor for measuring the pressure in the charge volume. However, this technique is much less reliable for precursors having relatively lower vapor pressure (e.g., lower than about 1.5× the gauge error). In such cases, the random gauge error can effectively swamp out the signal from the precursor, such that no reliable measurement can be made. For instance, the pressure sensor typically operates in the Torr regime, while the precursor may have a partial pressure in the mTorr regime. A further drawback of this technique is that it does not truly represent the flow rate of precursor being delivered to the processing chamber, because it relates to the rate of precursor delivery achieved from natural evaporation, rather than the rate of precursor delivery that is achieved when a flow of inert gas is actively sweeping the precursor away from the ampoule. Moreover, the two pressure measurements are taken at different times, rather than simultaneously, which may introduce further errors.

Another technique that has been used to estimate the precursor flow in a flow-over-vapor system involves sound velocity metrology. For instance, the Piezocon Gas Concentration Sensor, available from Veeco in Plainview, NY, may be used to estimate the concentration of precursor in the combined precursor and inert gas flow. With this technique, an acoustic pulse is propagated through a gas sample and then measured. The time required to propagate the pulse is determined, and the speed of sound through the sample is computed. This information, together with temperature and other gas-specific physical attributes, is used to compute the concentration of the individual gases (e.g., precursor and inert gas) in the sample. While this technique has the advantage of being a direct measurement, it shows a low signal-to-noise ratio when the concentration of precursor is low (e.g., when the combined gas flow of precursor and inert gas is about 0.2% precursor or less). As such, there are many circumstances where such a technique is not particularly helpful.

A further technique that has been used to estimate the precursor flow in a flow-over-vapor system involves Fourier-Transform Infrared Spectroscopy (FTIR). This technique involves measuring the infrared spectrum of absorption or emission of the combined precursor plus inert gas flow. An FTIR spectrometer simultaneously collects high-resolution spectral data over a wide spectral range, indicating how much light the sample absorbs at each wavelength. FTIR techniques can be very precise if a signature line in the spectrum can be identified and attributed to the relevant precursor. However, such techniques are very expensive. Moreover, FTIR techniques involve signal averaging. Due to the relatively short timeframes/temporal resolution involved with many precursor delivery schemes (e.g., especially in the context of atomic layer deposition, atomic layer etching, and other processing methods that involve short (e.g., <1 second) pulses of precursor delivery), such signal averaging is not practicable.

In various examples herein, a new technique is used for measuring the dose of precursor delivered to a processing chamber in the context of a flow-over-vapor precursor delivery system. Generally speaking, the technique involves splitting a flow of a carrier gas into a first stream and a second stream, adding the precursor to the second stream, and measuring a differential pressure between the first stream and the second stream. In some examples, the technique involves providing two charge volumes in the precursor delivery system and measuring the differential pressure between these two charge volumes. In other cases, these charge volumes may be omitted and the differential pressure between the first and second streams may be measured directly. As compared to the bypass-enabled differential metrology technique described above, certain examples herein use two (rather than one) charge volume (or other measurement spot), thereby enabling simultaneous, rather than asynchronous, measurement of (a) the combined flow of precursor and inert gas, and (b) the flow of inert gas only. This simultaneous measurement is a substantial improvement over the asynchronous measurement described above.

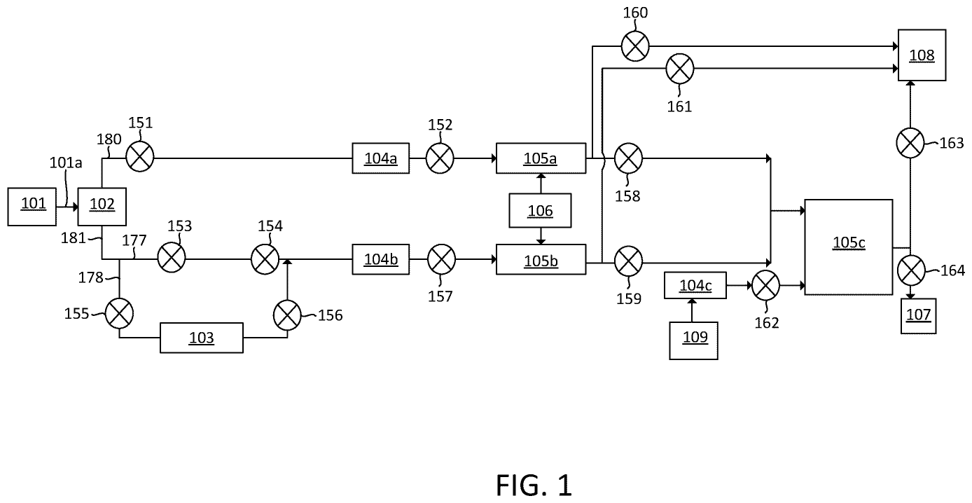

FIG. 1 presents a simplified view of a flow-over-vapor gas delivery system that may be used in various examples. The carrier gas source 101 (e.g., typically an inert gas such as one mentioned above) provides a carrier gas to the system via an inlet 101a. The carrier gas then flows into a flow splitter 102, which splits the flow into two streams. A first stream enters a first pathway 180 (shown extending upward from flow splitter 102), and acts as a reference stream, as no precursor gas is added to this stream. A second stream enters a second pathway 181 (shown extending downward from flow splitter 102), and is the stream to which the precursor gas is added. Specifically, the second stream is split into a first leg 177 and a second leg 178, and the precursor is provided via ampoule 103, which is positioned in the second leg 178. Ampoule 103 is an ampoule designed for flow-over-vapor applications.

Each of these first and second pathways 180 and 181 may include an optional flow control device, such as first mass flow controller 104a in the first pathway 180 and second mass flow controller 104b in the second pathway 181. Alternatively or in addition to the first and second mass flow controllers 104a and 104b, other types of flow control devices such as restricted flow orifices can be used. While these flow control devices are not required to perform the methods herein, they make such methods easier to control and accomplish. Where such flow control devices are used, they may be precision matched between the first and second pathways 180 and 181. In other words, first and second mass flow controllers 104a and 104b may be precision matched in terms of manufacturer, batch, material, material properties, geometry, size, etc. Similarly, the processing conditions (e.g., temperature) may be precision matched, as well. When other types of flow control devices are used, they may be similarly precision matched in terms of these same characteristics. As used herein, the term precision matched is intended to mean that the relevant pieces of hardware differ by less than about 1% with respect to a relevant characteristic (e.g., dimension, property, etc.). In some cases, this precision matching is even more precise, for example differing by less than about 0.5%, or less than about 0.1%. With regard to temperature, the first and second pathways 180 and 181 may be precision matched by ensuring that the pathways are within about 1° C. of one another, in some cases within about 0.5° C. of one another, or about 0.1° C. of one another. The first and second pathways 180 and 181 may also be maintained at an isothermal temperature, minimizing or eliminating temperature changes for each pathway. Similarly, the streams within the pathways may be precision matched by ensuring that the streams are within about 1° C., or about 0.5° C., or about 0.1° C. of one another. The streams may also be maintained at an isothermal temperature, minimizing or eliminating temperature changes for each stream.

Although FIG. 1 shows the second mass flow controller 104b downstream from the ampoule 103, other arrangements are possible. For instance, it may be beneficial to position the second mass flow controller 104b upstream from the ampoule 103 to ensure that any corrosive or otherwise harsh chemistry is not exposed to the second mass flow controller 104b.

A first charge volume 105a is provided in the first pathway 180, and a second charge volume 105b is provided in the second pathway 181. Much like the mass flow controllers 104a and 104b, the first and second charge volumes 105a and 105b may be precision matched to one another with respect to one or more characteristics mentioned above. For instance, the first and second charge volumes 105a and 105b may be made by the same manufacturer, from the same batch, using the same materials, having the same material properties, the same geometry and size, and they may be maintained at the same temperature, etc.

A differential pressure gauge 106 directly measures the differential pressure between the first charge volume 105a and the second charge volume 105b. The difference in pressure is attributed to the precursor. The differential pressure gauge 106 allows for far more precise and accurate measurement of the difference in pressure between the first charge volume 105a and the second charge volume 105b, as compared to measuring the individual pressures in the first charge volume 105a and the second charge volume 105b and comparing them. Similarly, the differential pressure gauge 106 allows for simultaneous measurement of the first and second streams in the first and second charge volumes 105a and 105b, which is a substantial advantage over previous methods that involved asynchronous measurements for a single charge volume.

After passing through the first charge volume 105a, the first pathway 180 can direct the first stream to a vacuum source 108 and/or to a third charge volume 105c. As opposed to the first and second charge volumes 105a and 105b, there is little or no benefit from ensuring that the third charge volume 105c is precision matched to the other charge volumes. As such, the third charge volume 105c may differ from the first and second charge volumes 105a and 105b.

After passing through the second charge volume 105b, the second pathway 181 can direct the second stream to the vacuum source 108 and/or to the third charge volume 105c. The first and second streams can optionally be combined in the third charge volume 105c. The third charge volume 105c may also be fed by an additional gas source 109. Gas source 109 may provide an inert gas or another processing gas to the third charge volume 105c. In some cases the gas provided by gas source 109 may be the same type of gas that is provided by carrier gas source 101. In other cases, these two gases are different. The gas stream introduced by gas source 109 may be referred to as the third gas stream or the third stream. The third gas stream may similarly include a third mass flow controller 104c, or other type of flow control device. After passing through the third charge volume 105c, the combined gas flow can be routed to a processing chamber 107 and/or to the vacuum source 108. The processing chamber 107 is where substrates are processed. Valves 150, 151, 152, 153, 154, 155, 156, 157, 158, 159, 160, 161, 162, 163, and 164 may be provided to control flow through the system as needed. In various examples, the third charge volume 105c may be discharged to the processing chamber 107 upon reaching a target pressure in the third charge volume 105c.

In addition to precision matching the first and second mass flow controllers 104a and 104b, as well as precision matching the first and second charge volumes 105a and 105b, it is desirable to match the remaining portions of the first and second pathways 180 and 181 within the gas delivery system, to the extent possible. For instance, the lengths and diameters of the piping used between analogous portions of the first and second pathways 180 and 181 may be identical or substantially the same (e.g., differing by no more than about 10%, or no more than about 5%, or no more than about 1%). This matching helps ensure that the reading provided by the differential pressure gauge 106 accurately represents the pressure added as a result of the precursor from the ampoule 103, rather than any differences in geometry or other factors between the first and second pathways 180 and 181. Differences in pressure between the first and second charge volumes 105a and 105b that arise due to geometry (e.g., non-uniformities between the first and second pathways 180 and 181) or other non-precursor related factors can be measured and removed from the calculation, as described further below.

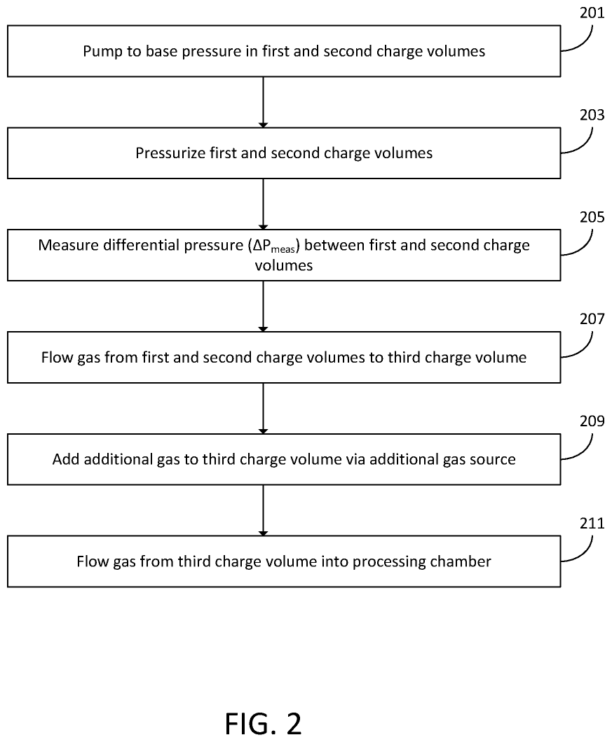

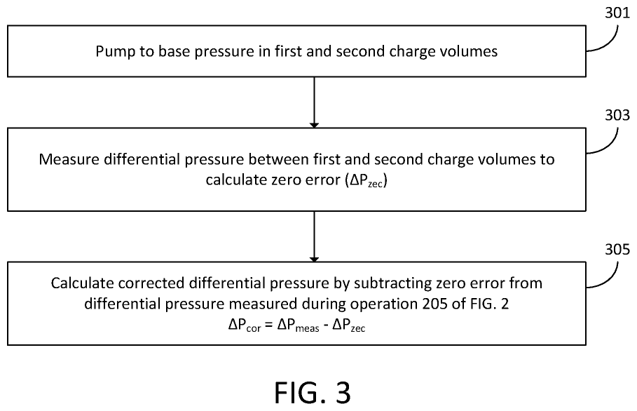

FIG. 2 presents a flowchart describing a method of measuring the dose of precursor provided to a processing chamber using the flow-over-vapor precursor delivery system shown in FIG. 1. As used herein, a “dose” of a precursor is understood to refer to an amount of precursor (e.g., mass of precursor) to be delivered to a processing chamber for processing a substrate (or for simultaneously processing a group of substrates). The dose is provided to the processing chamber by flowing a precursor-containing stream into the processing chamber over a period of time. The method of FIG. 2 will be described in the context of FIG. 1. The method begins with operation 201, where the first charge volume 105a, second charge volume 105 b, and third charge volume 105c are pumped/evacuated to their base pressure. This can be accomplished by opening valves 160, 161, and 163, while ensuring that all other valves are closed. After the charge volumes are pumped/evacuated to their base pressure, valves 160, 161, and 163 are closed. Next, at operation 203 the first charge volume 105a and the second charge volume 105b are pressurized while the second pathway 181 and second stream are in fluidic communication with the ampoule 103. This can be accomplished by opening valves 151, 152, 155, 156, and 157. After the first charge volume 105a and the second charge volume 105b are pressurized, all the valves can be closed.

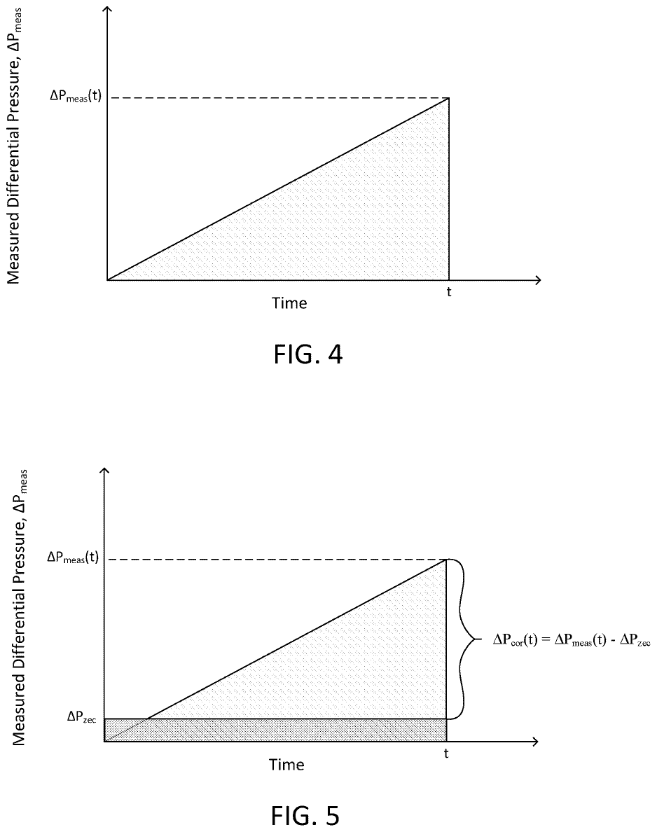

Next, at operation 205 the differential pressure between the first charge volume 105a and the second charge volume 105b is measured using the differential pressure gauge 106, also referred to as the pressure gauge. This differential pressure is referred to as the measured differential pressure, ΔPₘₑₐₛ, and is attributed at least in part to the presence of the precursor molecules entrained in the second stream after the second stream passes over ampoule 103. In various examples, this measurement may be modified by subtracting out the “zero error” as discussed further below in the context of FIGS. 3 and 5. In these or other examples, operation 205 may further include determining the precursor dose based on the measured differential pressure. A technique for calculating the precursor dose based on the measured differential pressure is discussed further below in the context of FIGS. 4 and 5.

At operation 207, the gas is flowed from the first charge volume 105a and the second charge volume 105b to the third charge volume 105c. This can be accomplished by opening valves 158 and 159. After the gas is flowed from the first and second charge volumes 105a and 105b into the third charge volume 105c, valves 158 and 159 can be closed. At operation 209, an additional gas may be introduced to the third charge volume 105c via the additional gas source 109. This additional gas is often argon or another inert gas used to dilute the combined precursor and carrier gas stream to a desired precursor concentration. It may be preferable to do this dilution downstream from the precursor dose measurement (e.g., downstream from the differential pressure gauge 106, as shown), such that the additional gas does not contribute to differential pressure reading, where it could increase the relevant pressure measurement error. In other words, it may be preferable to measure the precursor dose using as little carrier gas as possible, and later dilute the precursor plus carrier gas stream as needed to reduce measurement errors. The additional gas may be provided to the third charge volume 105c by opening valve 162. Valve 162 may remain open until the third charge volume 105c reaches a target pressure. At this point, valve 162 (and all other valves) may be closed. Next, at operation 211, gas is flowed from the third charge volume 105c into the processing chamber 107. This may be accomplished by opening valve 164. At this point, the gas stream includes the precursor gas originating from ampoule 103, the carrier gas originating from carrier gas source 101, and any additional gas originating from additional gas source 109. This gas stream is flowed into the processing chamber where it interacts with a semiconductor substrate, for example in a deposition or etching process.

The method described in FIG. 2 may be performed at any desired frequency. In some cases, the method may be performed each time a precursor is delivered to a processing chamber. In the context of cyclic processes such as atomic layer deposition and atomic layer etching where the precursor is repeatedly dosed into the processing chamber, the method may be performed during each cycle, or once per n cycles. In some cases, the method may be performed once per substrate, or once per batch of substrates (e.g., a batch being defined as a collection of substrates that are processed in a single chamber between a first chamber cleaning and a second chamber cleaning, with the processing typically occurring at different times such that substrates are processed serially). In some cases, the method may be performed periodically, such as once per hour, once per day, once per week, etc. Many different schedules are possible.

As mentioned above, the first and second pathways 180 and 181 (as well as any components therein such as the first and second mass flow controllers 104a and 104b, and the first and second charge volumes 105a and 105b) should be precision matched to one another to the extent possible. This matching helps ensure that the differential pressure measured by the differential pressure gauge (ΔPₘₑₐₛ) accurately represents the pressure increase arising from the precursor originating from the ampoule 103, rather than any geometric or other differences between the first and second pathways 180 and 181. In order to correct for any differences in these pathways, a zero error correction can be performed. With this technique, the differential pressure (if any) between the first and second pathways 180 and 181 is measured in the absence of any precursor from ampoule 103. The measured differential pressure at this point is referred to as the “zero error” (ΔP_{zec}) and represents baseline differences between the first and second pathways 180 and 181. During the method of FIG. 2, this zero error (ΔP_{zec}) can be subtracted out from the measured differential pressure (ΔPₘₑₐₛ) to determine a corrected differential pressure (ΔP_{cor}) that accounts for any differences between the first and second pathways 180 and 181.

FIG. 3 presents a flowchart describing a method of measuring and correcting for the zero error. This method may be used in the context of FIG. 2 to improve the accuracy of the differential pressure value used to calculate the dose of precursor. In other words, the method of FIG. 2 may be modified to include one or more of the steps described in FIG. 3. Like FIG. 2, the method of FIG. 3 is described with respect to system shown in FIG. 1. The method of FIG. 3 begins with operation 301, where the first charge volume 105a and second charge volume 105b are pumped/evacuated to their base pressure. This can be accomplished by opening valves 160 and 161 while the other valves remain closed. After the first charge volume 105a and second charge volume 105b reach their base pressure, valves 160 and 161 are closed. Next, at operation 303 the differential pressure between the first charge volume 105a and the second charge volume 105b is measured using the differential pressure gauge 106. This differential pressure is referred to as the “zero error” and is represented by the symbol ΔP_{zec}.

As noted above, the zero error represents differences between the first and second pathways 180 and 181 that are unrelated to the presence of the precursor from the ampoule 103. To account for these differences and thereby improve the accuracy of the method of FIG. 2, the zero error (ΔP_{zec}) can be subtracted out from the measured differential pressure (ΔPₘₑₐₛ) when practicing the method of FIG. 2. As such, the method of FIG. 3 continues with operation 305, where a corrected differential pressure, referred to as ΔP_{cor}, is calculated by subtracting the zero error (ΔP_{zec}) from the differential pressure measured in operation 205 of FIG. 2 (ΔPₘₑₐₛ). In other words, ΔP_{cor}=ΔPₘₑₐₛ−ΔP_{zec}. This corrected differential pressure ΔP_{cor} can then be used to calculate the dose of precursor being provided to the processing chamber 107.

The zero error measurement can be used to flag when the system is performing outside of acceptable parameters. For instance, a threshold zero error can be selected based on expected or normal performance. In cases where the zero error is measured to be greater than this threshold, a controller can issue an alert indicating that the system is not functioning as expected. Alternatively or in addition, the controller can shut the apparatus down such that no further substrates are processed until the issue causing the increased zero error can be addressed.

Some operations described in FIG. 3 may be performed a single time. For instance, operations 301 and 303 may be performed a single time, with the zero error (ΔP_{zec}) being stored for future use. In other words, there is no need to perform operations 301 and 303 each time it is desired to calculate a corrected differential pressure (ΔP_{cor}), because the corrected differential pressure (ΔP_{cor}) can be calculated using a previously measured and stored value for the zero error (ΔP_{zec}). Of course, the zero error can be remeasured as often as desired, for example to account for possible differences between the first and second streams that may arise over time, or under a different set of processing conditions.

In certain examples, the method of FIG. 2 is modified to include all of the operations from FIG. 3. For instance, operations 301 and 303 may occur first to establish and measure the zero error (ΔP_{zec}), followed by operations 201, 203, and 205. After the differential pressure between the first charge volume 105a and the second charge volume 105b is measured in operation 205, the corrected differential pressure (ΔP_{cor}) is calculated as described in operation 305, using the zero error (ΔP_{zec}) measured in operation 303. This corrected differential pressure (ΔP_{cor}) is used to calculate the dose of precursor provided by the ampoule 103, as described further herein. The method of FIG. 2 continues with operations 207, 209, and 211 to flow the precursor to the processing chamber 107, as needed.

In a similar example, the method of FIG. 2 is modified to include some, but not all, of the operations from FIG. 3. For instance, the method may occur as described in the preceding example, but without performing operations 301 and 303. Instead, the corrected differential pressure (ΔP_{cor}) is calculated based on a previously stored value of the zero error (ΔP_{zec}).

The zero error (ΔP_{zec}) may be measured a single time or multiple times, for example at times when the system is otherwise idle (e.g., not actively processing substrates). In cases where the zero error (ΔP_{zec}) is measured multiple times, the zero error used for calculating the corrected differential pressure (ΔP_{cor}) may be the most recently measured zero error, or an average of such measurements.

Measuring the differential pressure between the first charge volume 105a and the second charge volume 105b (whether corrected as described in FIG. 3 or not) allows for calculation of the dose of precursor provided by the flow-over-vapor system shown in FIG. 1. One technique for calculating the dose of precursor based on the measured differential pressure (ΔPₘₑₐₛ), without accounting for the zero error correction (ΔP_{zec}), is described below in the context of FIG. 4. Another technique for calculating the dose of precursor based on the measured differential pressure (ΔPₘₑₐₛ), which includes accounting for the zero error correction (ΔP_{zec}), is described below in the context of FIG. 5.

FIG. 4 depicts a chart showing pressure vs. time. The pressure refers to the measured differential pressure (ΔPₘₑₐₛ) between the first charge volume 105a and the second charge volume 105b, as measured by the differential pressure gauge 106. As described above, it is particularly beneficial to directly measure the differential pressure between these two charge volumes, rather than measuring the absolute pressure in each charge volume and calculating the difference between them, due to the relatively large errors associated with the absolute pressure measurements in comparison to the small incremental pressure added by the precursor from the ampoule 103. The use of the differential pressure gauge 106 substantially reduces the signal-to-noise ratio in the resulting measurement. This provides a significant improvement in accuracy over previous dose calculation methods.

As shown in FIG. 4, at time (t), the measured differential pressure is ΔPₘₑₐₛ(t). The dose of precursor can be calculated from this measurement using standard chemistry, e.g., PV=nRT, or n=PV/(RT), where P is the measured differential pressure at time t (e.g., ΔPₘₑₐₛ(t)), V is the individual volume of each of the first and second charge volumes 105a and 105b, R is the ideal gas constant, and T is temperature. Modified calculations can be used in cases where the relevant gas(es) behave in a non-ideal manner, as understood by those of ordinary skill in the art.

While the technique described above and shown in FIG. 4 provides a reasonable estimate of the dose of precursor provided by the ampoule 103, it does not consider the zero error correction described above in relation to FIG. 3. In order to improve the accuracy of the dose calculation, the corrected differential pressure (ΔP_{cor}) can be used instead of the measured differential pressure (ΔPₘₑₐₛ). FIG. 5 illustrates a chart similar to the one shown in FIG. 4, but further showing the zero error (ΔP_{zec}). The zero error is measured as described in FIG. 3, and for purposes of the calculation in FIG. 5 is treated as a constant. The corrected differential pressure (ΔP_{cor}) can be calculated for a given time as follows: ΔP_{cor}(t)=ΔPₘₑₐₛ(t−ΔP_{zec}. The dose of precursor is then calculated using standard chemistry as described in relation to FIG. 4, using the corrected differential pressure (ΔP_{cor}) instead of the measured differential pressure (ΔPₘₑₐₛ) to improve accuracy.

Using the techniques described in relation to FIGS. 4 and 5, a target dose of a precursor can be delivered to the processing chamber for processing a substrate. One of ordinary skill in the art would appreciate that the target dose can be achieved by selecting an appropriate target differential pressure (e.g., measured differential pressure or corrected differential pressure, depending on whether the zero error is corrected for). It is understood that once the differential pressure reaches its target, it means that the target dose of the precursor has been entrained in the carrier gas provided in the second stream, and the dose can be provided to the substrate in the processing chamber at that time.

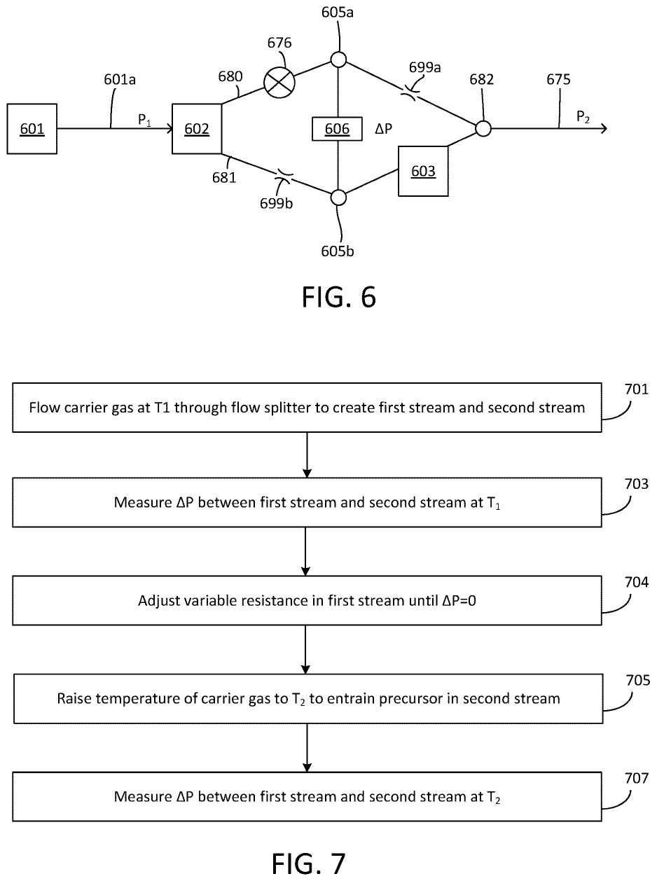

FIG. 6 shows another example of a simplified precursor delivery system. This example is very similar to the one shown in FIG. 1, but in this case no charge volumes are required. Carrier gas source 601 (analogous to carrier gas source 101 of FIG. 1) provides a carrier gas to the system via an inlet 601a at a first pressure, P1. The carrier gas then flows into a flow splitter 602, which splits the flow into a first stream and a second stream. The first stream enters a first pathway 680, and the second stream enters a second pathway 681. Ampoule 603 (analogous to ampoule 103 of FIG. 1) is positioned in the second pathway 681 and includes a precursor for flow-over-vapor applications. A first flow control device 676 (e.g., which may be a valve or other type of variable resistance orifice) is positioned in the first pathway 680. In addition, a second flow control device 699a is positioned in the first pathway 680, and a third flow control device 699b is positioned in the second pathway 681. Flow control devices 699a and 699b may be fixed orifices that each provide a fixed resistance. Flow control devices 699a and/or 699b could also be variable orifices that are capable of providing variable resistances. In many cases, flow control devices 699a and 699b may be operated as fixed orifices for the purpose of obtaining accurate baseline measurements for determining differential pressure, as explained in relation to FIG. 7, below. The position of flow control devices 676, 699a, and 699b, as well as ampoule 603 are interchangeable with one another. Generally speaking, the structure created by the various flow paths/orifices/ampoule shown in FIG. 6 is analogous to a Wheatstone bridge in an electrical circuit. A Wheatstone bridge can be used to measure an unknown electrical resistance by balancing two legs of a bridge circuit, one leg of which includes the component having the unknown electrical resistance. Ampoule 603 is analogous to the component having the unknown electrical resistance in the Wheatstone bridge.

A differential pressure gauge 606 (analogous to differential pressure gauge 106) is provided to measure the differential pressure between (i) location 605a positioned in the first pathway 680, and (ii) location 605b positioned in the second pathway 681. Location 605a and location 605b may be within the piping or other hardware for the first pathway 680 and for the second pathway 681, respectively. In other words, no separate charge volumes are required, and the differential pressure measurement can be made directly between the first stream in the first pathway 680 and the second stream in the second pathway 681. In various examples, the differential pressure gauge 606 includes a membrane that physically separates the first stream in the first pathway 680 from the second stream in the second pathway 681.

The first pathway 680 and the second pathway 681 rejoin at location 682 to create stream 675, at pressure P₂, which may be provided to a processing chamber, mixing vessel, or other processing hardware. While FIG. 6 omits many of the features shown in FIG. 1, it is understood that the example of FIG. 6 may be implemented in the system of FIG. 1 (e.g., omitting the first and second charge volumes, as described), or in a similar system. As such, features from FIG. 1 may be combined with the example of FIG. 6 as desired for a particular case.

As discussed in relation to FIG. 1, the first pathway 680 and the second pathway 681 may be precision matched to one another, with the goal of providing substantially identical flow resistance in the two pathways. Similarly, locations 605a and 605b may be precision matched to one another with respect to their positions in the first pathway 680 and second pathway 681, respectively. The first flow control device 676 may be tuned to achieve substantially identical flow resistance in the first pathway 680 and second pathway 681, as discussed further below. In some cases, an optional empty ampoule (not shown) may be provided in the first pathway 680 in order to mimic the effect of ampoule 603 in the second pathway 681.

FIG. 7 provides a flowchart for a method of measuring a dose of a precursor provided to a processing chamber using the precursor delivery system shown in FIG. 6. For the sake of clarity, the method of FIG. 7 will be explained with reference to the precursor delivery system of FIG. 6. The method of FIG. 7 begins at operation 701, where a carrier gas is flowed at temperature T₁ from a carrier gas source 601 to a flow splitter 602, which splits the flow of carrier gas into a first stream that passes through a first pathway 680 and a second stream that passes through a second pathway 681. At operation 703, the differential pressure is measured between the first stream and the second stream at temperature T₁. This measurement is done via the differential pressure gauge 606, which measures the differential pressure between (i) location 605a in the first pathway 680, and (ii) location 605b in the second pathway 681. At operation 704, the first flow control device 676 may be tuned such that the differential pressure between locations 605a and 605b is zero, or as close to zero as possible.

Temperature T₁ is set sufficiently low that substantially no precursor becomes entrained in the second stream in the second pathway 681. The ideal T₁ temperature will depend on the identity and volatility of the precursor, with more volatile precursors using relatively lower T₁ to avoid entraining the precursor in the second pathway 681 during operation 703. Essentially, operation 703 is used to create a baseline to which a subsequent differential pressure measurement can be compared.

At operation 705, the temperature of the carrier gas is raised to T₂. T₂ is greater than T₁, and is sufficiently high to entrain a desired amount of precursor from ampoule 603 into the second stream in the second pathway 681. Next, at operation 707, the differential pressure is again measured between the first stream at location 605a and the second stream at location 605b, this time at temperature T₂. The difference between (a) the differential pressure measured in operation 707 when substantially no precursor is present in the second stream, and (b) the differential pressure measured in operation 703 when precursor is present in the second stream can be used to determine the amount of precursor that has been entrained in the carrier gas. For instance, it can be assumed that all or substantially all of the difference in differential pressure at the two temperatures is due to introduction of the precursor. As such, the degree of change in differential pressure indicates the amount of precursor being provided.

The dose control system described in FIGS. 1 and 6 may be incorporated into any type of apparatus or system for processing semiconductor substrates. The dose control system is particularly useful in apparatus/systems where precise dose control is desired in a flow-over-vapor system. Such systems are particularly beneficial for delivering low vapor pressure precursors, especially those that break down or cause corrosion or other issues when heated. The dose control system described herein may be used in connection with deposition, etching, substrate treatment, etc. The particulars of the processing apparatus (e.g., processing chamber 107 of FIG. 1) are not especially relevant, as the system described herein can be incorporated into many different kinds of substrate processing apparatuses. As such, for the sake of brevity, only a single example deposition apparatus is described. However, it should be understood that the dose control system herein can be applied to many different types of substrate processing apparatuses.

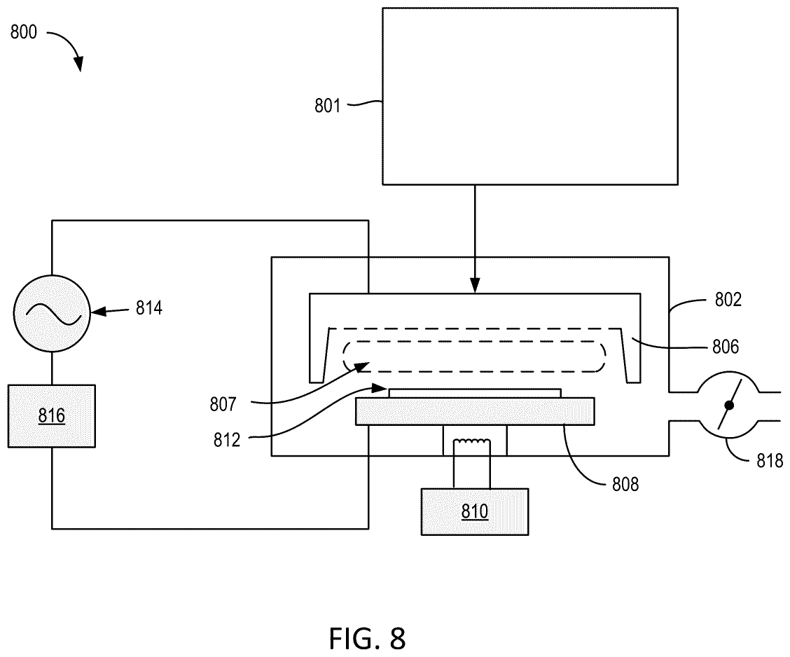

FIG. 8 schematically shows an example of a process station 600 that may be used to deposit material using atomic layer deposition (ALD) and/or chemical vapor deposition (CVD), either of which may be plasma enhanced. Precursors are fed to the process station 800 using the precursor delivery system 801, which corresponds to the dose control system shown in FIG. 1. For instance, the precursor delivery system 801 may include some or all of the features shown in the dose control system of FIG. 1 (excluding processing chamber 107 which corresponds to process chamber body 802). For illustrative purposes, the process station 800 is depicted as a standalone process station having process chamber body 802 for maintaining a low-pressure environment. However, it will be appreciated that a plurality of process stations 800 may be included in a common process tool environment. Further, it will be appreciated that, in some examples, one or more hardware parameters of process station 800 and/or precursor delivery system 801, including those discussed in detail herein, may be adjusted programmatically by one or more computer controllers.

Process station 800 fluidly communicates with precursor delivery system 801 for delivering process gases to a distribution showerhead 806. Precursor delivery system 801 includes some or all of the features from the dose control system described in relation to FIG. 1. Of course, one or more additional showerheads or other inlets (not shown) may be provided to deliver additional precursors or process gases. Similarly, more than one precursor delivery system 801 may be provided, for example in cases where more than one flow-over-vapor precursor is dosed into the process chamber body 802. The precursor delivery system 801 may also include additional features to deliver precursors, as desired. For instance, the precursor delivery system 801 may include various mixing vessels, and/or a vaporization point (not shown) for vaporizing liquid precursors. Additionally, any of the components in the precursor delivery system 801 may be heat traced or otherwise temperature-controlled, including any of the components of the dose control system in FIG. 1.

In some examples, the precursor delivery system may further include a liquid injector for vaporizing and introducing a liquid-phase precursor. For example, a liquid injector may inject pulses of a liquid precursor into a carrier gas stream upstream of a mixing vessel. Generally speaking, the precursor delivery system may be modified from the dose control system shown in FIG. 1 to include various additional features as needed to deliver all relevant precursors and processing gases to the process chamber body 802.

In some examples, a liquid flow controller or other controller may be provided for controlling a mass flow of liquid for vaporization and delivery to process station 800. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid precursor. Thus, in some examples, the LFC may be dynamically switched between a feedback control mode and a direct control mode. In some examples, the LFC may be dynamically switched from a feedback control mode to a direct control mode by disabling a sense tube of the LFC and the PID controller.

Showerhead 806 distributes process gases toward substrate 812. In the example shown in FIG. 8, substrate 812 is located beneath showerhead 806, and is shown resting on a pedestal 808. It will be appreciated that showerhead 806 may have any suitable shape, and may have any suitable number and arrangement of ports for distributing processes gases to substrate 812.

In some examples, a microvolume 807 is located beneath showerhead 806. Performing an ALD and/or CVD process in a microvolume rather than in the entire volume of a process station may reduce precursor exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some examples, pedestal 808 may be raised or lowered to expose substrate 812 to microvolume 807 and/or to vary a volume of microvolume 807. For example, in a substrate transfer phase, pedestal 808 may be lowered to allow substrate 812 to be loaded onto pedestal 808. During a deposition process phase, pedestal 808 may be raised to position substrate 812 within microvolume 807. In some examples, microvolume 807 may completely enclose substrate 812 as well as a portion of pedestal 808 to create a region of high flow impedance during a deposition process.

Optionally, pedestal 808 may be lowered and/or raised during portions the deposition process to modulate process pressure, precursor concentration, etc., within microvolume 807. In one scenario where process chamber body 802 remains at a base pressure during the deposition process, lowering pedestal 808 may allow microvolume 807 to be evacuated. Example ratios of microvolume to process chamber volume include, but are not limited to, volume ratios between 1:600 and 1:10. It will be appreciated that, in some examples, pedestal height may be adjusted programmatically by a suitable computer controller.

In another scenario, adjusting a height of pedestal 808 may allow a plasma density to be varied during plasma activation and/or treatment cycles included in the deposition process. At the conclusion of the deposition process phase, pedestal 808 may be lowered during another substrate transfer phase to allow removal of substrate 812 from pedestal 808.

While the example microvolume variations described herein refer to a height-adjustable pedestal, it will be appreciated that, in some examples, a position of showerhead 806 may be adjusted relative to pedestal 808 to vary a volume of microvolume 807. Further, it will be appreciated that a vertical position of pedestal 808 and/or showerhead 806 may be varied by any suitable mechanism within the scope of the present disclosure. In some examples, pedestal 808 may include a rotational axis for rotating an orientation of substrate 812. It will be appreciated that, in some examples, one or more of these example adjustments may be performed programmatically by one or more suitable computer controllers.

Returning to the example shown in FIG. 8, showerhead 806 and pedestal 808 electrically communicate with RF power supply 814 and matching network 816 for powering a plasma. In some examples, the plasma energy may be controlled by controlling one or more of a process station pressure, a gas concentration, an RF source power, an RF source frequency, and a plasma power pulse timing. For example, RF power supply 814 and matching network 816 may be operated at any suitable power to form a plasma having a desired composition of radical species. Examples of suitable powers are included above. Likewise, RF power supply 814 may provide RF power of any suitable frequency. In some examples, RF power supply 814 may be configured to control high-and low-frequency RF power sources independently of one another. Example low-frequency RF frequencies may include, but are not limited to, frequencies between 50 kHz and 600 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some examples, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some examples, one or more plasma parameters may be programmatically adjusted based on measurements from such in-situ plasma monitors. For example, an OES sensor may be used in a feedback loop for providing programmatic control of plasma power. It will be appreciated that, in some examples, other monitors may be used to monitor the plasma and other process characteristics. Such monitors may include, but are not limited to, infrared (IR) monitors, acoustic monitors, and pressure transducers.

In some examples, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some examples, instructions for setting one or more plasma parameters may be included in a recipe phase preceding a plasma process phase. For example, a first recipe phase may include instructions for setting a flow rate of an inert and/or a precursor gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various examples disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some examples, pedestal 808 may be temperature controlled via heater 810. Further, in some examples, pressure control for deposition process station 800 may be provided by butterfly valve 818. As shown in the example of FIG. 8, butterfly valve 818 throttles a vacuum provided by a downstream vacuum pump (not shown). However, in some examples, pressure control of process station 800 may also be adjusted by varying a flow rate of one or more gases introduced to process station 800.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, measurement and calculation of precursor doses, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some examples, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As used herein, the term “about” as applied to a number is intended to refer to a value within ±10% of the stated value.

### CONCLUSION

Although the foregoing examples have been described in some detail for purposes of clarity of understanding, it will be apparent that certain changes and modifications may be practiced within the scope of the appended claims. It should be noted that there are many alternative ways of implementing the processes, systems, and apparatus of the present examples. Accordingly, the present examples are to be considered as illustrative and not restrictive, and the examples are not to be limited to the details given herein.

1. A system for providing a precursor to a processing chamber, the system comprising:
an inlet configured to allow a flow of a carrier gas into the system;
a flow splitter in fluid communication with the inlet and configured to split the flow of the carrier gas into a first stream and a second stream, wherein the first stream is delivered to a first pathway and the second stream is delivered to a second pathway;
a first charge volume positioned in the first pathway, wherein the first stream passes through the first charge volume, and a second charge volume positioned in the second pathway, wherein the second stream passes through the second charge volume;
an ampoule comprising the precursor, the ampoule positioned within the second pathway, wherein when the second stream passes the ampoule at a sufficiently high temperature, the precursor is entrained within the second stream; and
a pressure gauge configured to measure a differential pressure between (i) a first location positioned in the first pathway, and (ii) a second location positioned in the second pathway.

2. The system of claim 1, wherein the first location is in the first charge volume and the second location is in the second charge volume, and wherein the first charge volume and the second charge volume are precision matched to one another.

3. The system of claim 2, further comprising a fourth flow control device positioned within the first pathway and a fifth flow control device positioned within the second pathway, wherein the fourth and fifth flow control devices are precision matched to one another.

4. The system of claim 3, wherein the fifth flow control device is upstream of the ampoule within the second pathway.

5. The system of claim 2, wherein the second pathway comprises a first leg and a second leg, the ampoule positioned within the second leg, and wherein a plurality of valves are provided in the second pathway to alternatively (a) allow for the ampoule to be in fluidic communication with the inlet and with the second charge volume such that the second stream passing through the second charge volume comprises both the carrier gas and the precursor, and (b) to prevent fluidic communication between the ampoule and either the inlet or the second charge volume such that the second stream passing through the second charge volume comprises the carrier gas and is absent the precursor.

6. The system of claim 1, further comprising a controller configured to cause measuring the differential pressure between the first location and the second location.

7. The system of claim 6, wherein the controller is further configured to cause determining a dose of precursor provided to the processing chamber based on the measured differential pressure between the first location and the second location.

8. The system of claim 7, wherein the controller is configured to cause determining the dose of precursor provided to the processing chamber based on the measured differential pressure between the first location and the second location, as modified by a zero error that accounts for differences between the first pathway and the second pathway.

9. The system of claim 8, wherein the zero error corresponds to a differential pressure between the first charge volume and the second charge volume after the first charge volume and the second charge volume have been evacuated to their base pressure and while the ampoule is not in fluidic communication with the second charge volume.

10. The system of claim 9, wherein the first pathway is maintained at a first temperature and the second pathway is maintained at a second temperature, the first and second temperatures being within about 1° C. of one another.

11. The system of claim 6, wherein the controller is configured to deliver a target dose of precursor to the processing chamber upon reaching a target differential pressure between the first location and the second location.

12. A system for providing a precursor to a processing chamber, the system comprising:
an inlet configured to allow a flow of a carrier gas into the system;
a flow splitter in fluid communication with the inlet and configured to split the flow of the carrier gas into a first stream and a second stream, wherein the first stream is delivered to a first pathway and the second stream is delivered to a second pathway;
a first flow control device, a second flow control device, and a third flow control device, wherein the first flow control device and the second flow control device are each positioned in the first pathway and the third flow control device is positioned in the second pathway, wherein the first stream passes through the first flow control device and through the second flow control device, wherein the second stream passes through the third flow control device, and wherein at least one of the first flow control device, the second flow control device, and/or the third flow control device is a variable flow control device configured to provide a variable flow resistance;
an ampoule comprising the precursor, the ampoule positioned within the second pathway, wherein when the second stream passes the ampoule at a sufficiently high temperature, the precursor is entrained within the second stream; and
a pressure gauge configured to measure a differential pressure between (i) a first location positioned in the first pathway, and (ii) a second location positioned in the second pathway.

13. The system of claim 12, further comprising a controller configured to cause measuring the differential pressure between the first location and the second location by:
measuring the differential pressure between the first location and the second location while the flow of the carrier gas is at a first temperature, the first temperature being sufficiently low that substantially no precursor is entrained in the second stream,
adjusting the variable flow resistance of the variable flow control device such that the differential pressure between the first location and the second location reads zero,
raising a temperature of the carrier gas from the first temperature to a second temperature, the second temperature being sufficiently high that the precursor becomes entrained in the second stream, and
measuring the differential pressure between the first location and the second location while the flow of the carrier gas is at the second temperature.

14. A method for determining a dose of precursor to be provided to a processing chamber, the method comprising:
splitting a flow of a carrier gas into a first stream delivered to a first pathway and a second stream delivered to a second pathway;
passing the second stream over an ampoule positioned in the second pathway, the ampoule comprising the precursor, wherein when the second stream passes the ampoule at a sufficiently high temperature, the precursor is entrained within the second stream;
passing the first stream into a first charge volume positioned in the first pathway, and passing the second stream into a second charge volume positioned in the second pathway;
measuring a differential pressure between the first change volume and the second charge volume; and
determining the dose of precursor to be provided to the processing chamber based on the measured differential pressure between the first charge volume and the second charge volume.

15. The method of claim 14, wherein determining the dose of precursor to be provided to the processing chamber comprises determining a corrected differential pressure between the first charge volume and the second charge volume, the corrected differential pressure corresponding to the measured differential pressure modified by a zero error that accounts for differences between the first pathway and the second pathway.

16. The method of claim 14, further comprising determining a zero error by measuring the differential pressure between the first charge volume and the second charge volume while the first charge volume and the second charge volume are evacuated to their base pressure and while the ampoule is not in fluidic communication with the second charge volume.

17. The method of claim 16, further comprising determining a corrected differential pressure between the first charge volume and the second charge volume by subtracting the zero error from the measured differential pressure between the first charge volume and the second charge volume, wherein the dose of precursor is determined based on the corrected differential pressure between the first charge volume and the second charge volume.

18. The method of claim 16, further comprising providing an alert and/or ceasing operation of the processing chamber upon detecting that the zero error is greater than a threshold zero error.

19. The method of claim 14, further comprising delivering a target dose of precursor to the processing chamber upon reaching a target differential pressure between the first charge volume and the second charge volume.

20. The method of claim 14, wherein the first stream and the second stream are provided to a third charge volume, wherein an additional gas is provided to the third charge volume to further dilute the precursor, and wherein the third charge volume is discharged to the processing chamber upon reaching a target pressure within the third charge volume.

21. A method for determining a dose of precursor to be provided to a processing chamber, the method comprising:
splitting a flow of a carrier gas into a first stream delivered to a first pathway and a second stream delivered to a second pathway;
passing the first stream through a first flow control device and through a second flow control device, wherein the first flow control device and the second flow control device are each positioned in the first pathway;
passing the second stream through a third flow control device positioned in the second pathway, and passing the second stream through or over an ampoule positioned in the second pathway, wherein the ampoule comprises the precursor, and wherein at least one of the first flow control device, the second flow control device, and/or the third flow control device is a variable flow control device configured to provide a variable flow resistance;
measuring a differential pressure between a first location positioned in the first pathway and a second location positioned in the second pathway while the carrier gas is at a first temperature;
adjusting the variable flow resistance of the variable flow control device such that the differential pressure between the first location and the second location is zero;
raising a temperature of the carrier gas to a second temperature, wherein the second temperature is sufficiently high to entrain some of the precursor in the second stream;
measuring the differential pressure between the first location and the second location while the carrier gas is at the second temperature; and
determining the dose of precursor based at least in part on the differential pressure measurements at the first temperature and at the second temperature.
